(19) United States
(12) Patent Application Publication
(10) Pub. No.: US 2010/0327391 A1
(43) Pub. Date: Dec. 30, 2010

(54) BACK-ILLUMINATED IMAGE SENSOR WITH ELECTRICALLY BIASED FRONTSIDE AND BACKSIDE

(76) Inventors: John P. McCarten, Penfield, NY (US); Cristian A. Tivarus, Rochester, NY (US); Joseph R. Summa, Hilton, NY (US)

Correspondence Address: Pedro P. Hernandez;Patent Legal Staff, Eastman Kodak Company, 343 State Street, Rochester, NY, 14650-2201, US

(21) Appl. No.: 12/492,343

(22) Filed: Jun. 26, 2009

(51) Int. Cl. H01L 27/146

(52) U.S. Cl. 257/447; 257/E27.13

(57) ABSTRACT

A back-illuminated image sensor includes a sensor layer of a first conductivity type having a frontside and a backside opposite the frontside. One or more regions of a second conductivity type are formed in at least a portion of the sensor layer adjacent to the frontside. The one or more regions are connected to a voltage terminal for biasing these regions to a predetermined voltage. A backside well of the second conductivity type is formed in the sensor layer adjacent to the backside. The backside well is electrically connected to another voltage terminal for biasing the backside well at a second predetermined voltage that is different from the first predetermined voltage.

### TECHNICAL FIELD

The present invention relates generally to image sensors for use in digital cameras and other types of image capture devices, and more particularly to back-illuminated image sensors.

### BACKGROUND

An electronic image sensor captures images using light-sensitive photodetectors that convert incident light into electrical signals. Image sensors are generally classified as either front-illuminated image sensors or back-illuminated image sensors. As the image sensor industry migrates to smaller and smaller pixel designs to increase resolution and reduce costs, the benefits of back-illumination become clearer. In front-illuminated image sensors, the electrical control lines or conductors are positioned between the photodetectors and the light-receiving side of the image sensor. The consequence of this positioning is the electrical conductors block part of the light that should be received by the photodetectors, resulting in poor quantum efficiency (QE) performance, especially for small pixels. For back-illuminated image sensors, the electrical control lines or conductors are positioned opposite the light-receiving side of the sensor and do not reduce QE performance. Back-illuminated image sensors therefore solve the QE performance challenge of small pixel designs.

FIG. 1 is a cross-sectional view of a portion of an NMOS back-illuminated image sensor with a frontside bias and backside bias in accordance with the prior art. In particular, FIG. 1 depicts a back-illuminated image sensor as disclosed in United States Patent Application Publication US2008/0217723. Frontside 102 of sensor layer 104 is conventionally known as the side of sensor layer 104 that abuts circuit layer 106, while the backside 108 of sensor layer 104 opposes the frontside 102. Backside 108 is typically coated with an insulating layer 110. This backside configuration allows light 112 to strike backside 108 and be detected by photodetectors 114. With a back-illuminated image sensor, light detection by photodetectors 114 is not impacted by metallization levels 116, gates 118, and other features of circuit layer 106. Frontside contact 120 is typically held at ground and is electrically connected to shallow p-well 122. Backside contact 124 is electrically connected to p-type region 126.

Pixel size is decreasing in an effort to increase the number of pixels 128 included in an image sensor. One advantage to smaller pixels is the increased resolution of an image for a fixed optical format. Specifically, smaller pixels have a better modulation transfer function (MTF), and can thus discriminate fine details in an image, such as the lines on a thinly striped shirt. However, with a back-illuminated image sensor, reducing the size of pixels 128 does not necessarily improve MTF performance because the electric field within sensor layer 104 near backside 108 is low. Photogenerated carriers that are created within a low electric field region can diffuse laterally. Specifically, at room temperature, photocarriers can diffuse against electric fields of less than 1000 V/cm in magnitude with significant probability. Carriers that diffuse laterally have a significant probability of being collected by the photodetectors 114 in adjacent pixels. Low electric field regions near backside 108 lead to poor MTF performance and therefore poor color crosstalk performance.

MTF performance can be improved in the back-illuminated n-channel metal oxide semiconductor (NMOS) image sensor of FIG. 1 when a negative bias is applied to backside contact 124 and ground applied to frontside contact 120. A negative backside bias on contact 124 creates an electric field from the backside 108 to the frontside 104 that forces the photogenerated electrons 130 into the nearest photodetector 114. Biasing the backside p-type region 126 at a different voltage than frontside p-well 122 requires the two p-type regions 122, 126 to be separated by an n-type region. The two contacts 120, 124 are ohmically shorted together without an intervening n-type region.

As illustrated in FIG. 1, this leads to a pixel design with extra n-type implants 132, effectively creating a triple-well design. In this triple well design, the n+ charge-to-voltage conversion mechanism 134 resides in p-well 122. The shallow p-well 122 is biased by contact 120 through other p-type implants, including p-type implants 136, 138.

The triple well design creates more performance related issues than it solves. First, the addition of the triple well increases the footprint of the pixel transistors and shrinks the size of photodetectors 114, thereby reducing photodetector capacity. Second, surrounding the shallow p-well 122 and p-type implants 136, 138 with the n-type photodetector 114 and n-type implant 132 adversely impacts the manufacturability of transfer gates 118. The p+ implants 136 must be pulled back from transfer gates 118 in order to isolate the p+ implant 136 from the p− epitaxial layer of sensor layer 104. The small n-type regions that are part of photodetector 114 disposed between p+ implants 136 and transfer gates 118 create pockets that degrade lag performance. Third, the combination of n− implant 132, p-well 122, and n-type charge-to-voltage conversion mechanism 134 under and adjacent to transfer gate 118 also leads to lag performance issues during manufacturing. This is because of the need to tightly control alignment. Fourth, the region of the triple well where there is a sharp n-p-n junction just under transfer gate 118 creates a high electric field region that enhances bright point generation.

### SUMMARY

A back-illuminated image sensor includes a sensor layer of a first conductivity type having a frontside and a backside opposite the frontside. An insulating layer is disposed over the backside. A plurality of photodetectors of the first conductivity type convert light incident on the backside into photo-generated charges. The photodetectors are disposed in the sensor layer adjacent to the frontside. One or more regions of a second conductivity type are formed in at least a portion of the sensor layer adjacent to the frontside. The one or more regions are connected to a voltage terminal for biasing these regions to a predetermined voltage. A backside well of the second conductivity type is formed in the sensor layer adjacent to the backside. The backside well is electrically connected to another voltage terminal for biasing the backside well at a second predetermined voltage that is different from the first predetermined voltage. The voltage difference creates an electric field between the frontside and the backside of the sensor layer.

### Advantages

The present invention has the advantage of providing a back-illuminated image sensor with improved cross talk performance.

### BRIEF DESCRIPTION OF THE DRAWINGS

Embodiments of the invention are better understood with reference to the following drawings. The elements of the drawings are not necessarily to scale relative to each other.

FIG. 1 is a cross-sectional view of a portion of an NMOS back-illuminated image sensor with a frontside bias and backside bias in accordance with the prior art;

FIG. 2 is a simplified block diagram of an image capture device in an embodiment in accordance with the invention;

FIG. 3 is a simplified block diagram of image sensor 206 shown in FIG. 2 in an embodiment in accordance with the invention;

FIG. 4 is a schematic diagram illustrating an exemplary implementation for pixel 300 shown in FIG. 3;

FIG. 5 is a cross-sectional view of a portion of a first back-illuminated image sensor in an embodiment in accordance with the invention;

FIG. 6 is a top view of a portion of a second back-illuminated image sensor and an electrically bias light shield in an embodiment in accordance with the invention;

FIG. 7 is a cross-sectional view through the line A-A′ shown in FIG. 6; and

FIG. 8 is a cross-sectional view of a portion of a third back-illuminated image sensor in an embodiment in accordance with the invention.

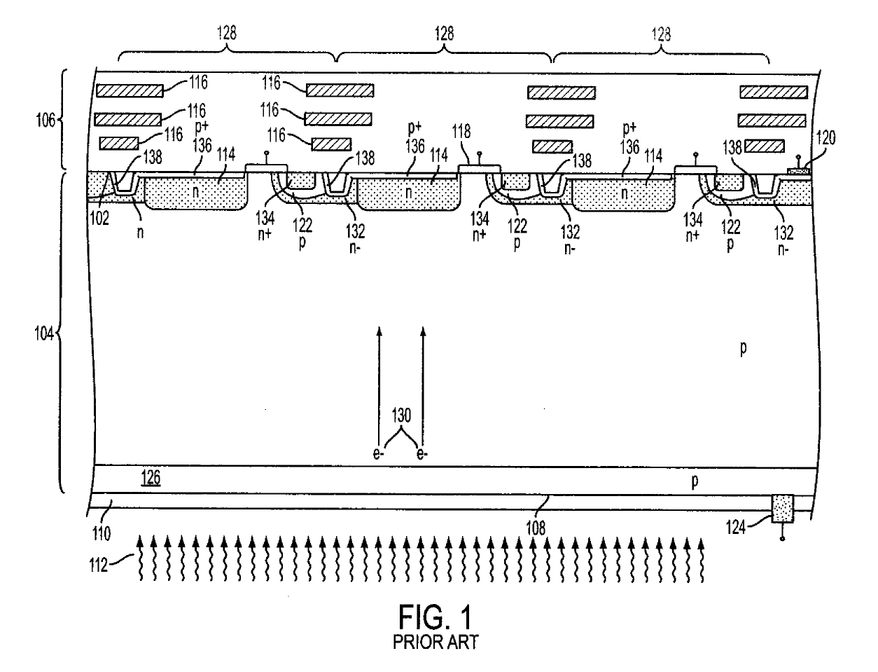

### DETAILED DESCRIPTION

Throughout the specification and claims the following terms take the meanings explicitly associated herein, unless the context clearly dictates otherwise. The meaning of “a,” “an,” and “the” includes plural reference, the meaning of “in” includes “in” and “on.” The term “connected” means either a direct electrical connection between the items connected or an indirect connection through one or more passive or active intermediary devices. The term “circuit” means either a single component or a multiplicity of components, either active or passive, that are connected together to provide a desired function. The term “signal” means at least one current, voltage, or data signal.

Additionally, directional terms such as “on”, “over”, “top”, “bottom”, are used with reference to the orientation of the Figure(s) being described. Because components of embodiments of the present invention can be positioned in a number of different orientations, the directional terminology is used for purposes of illustration only and is in no way limiting. When used in conjunction with layers of an image sensor wafer or corresponding image sensor, the directional terminology is intended to be construed broadly, and therefore should not be interpreted to preclude the presence of one or more intervening layers or other intervening image sensor features or elements. Thus, a given layer that is described herein as being formed on or formed over another layer may be separated from the latter layer by one or more additional layers.

Referring to the drawings, like numbers indicate like parts throughout the views.

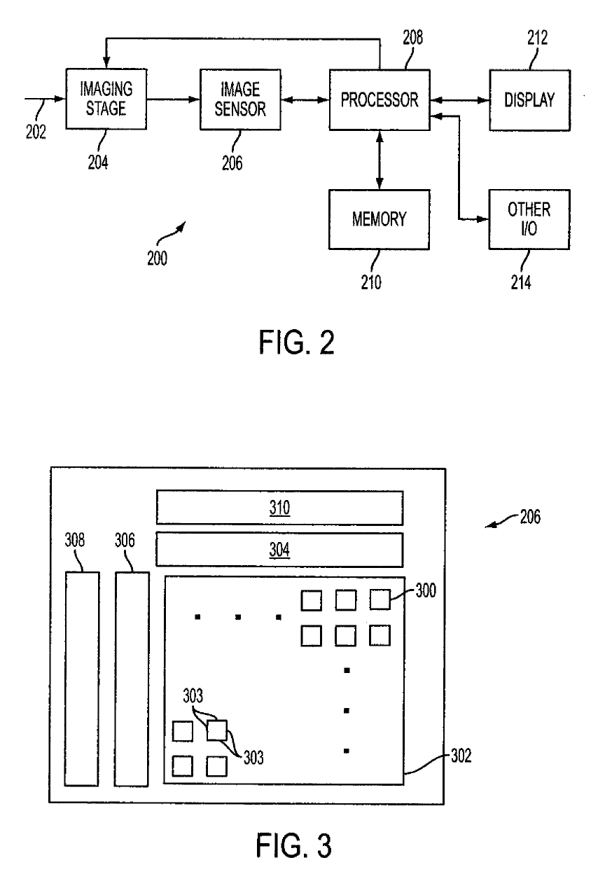

FIG. 2 is a simplified block diagram of an image capture device in an embodiment in accordance with the invention. Image capture device 200 is implemented as a digital camera in FIG. 2. Those skilled in the art will recognize that a digital camera is only one example of an image capture device that can utilize an image sensor incorporating the present invention. Other types of image capture devices, such as, for example, cell phone cameras, scanners, and digital video camcorders, can be used with the present invention.

In digital camera 200, light 202 from a subject scene is input to an imaging stage 204. Imaging stage 204 can include conventional elements such as a lens, a neutral density filter, an iris and a shutter. Light 202 is focused by imaging stage 204 to form an image on image sensor 206. Image sensor 206 captures one or more images by converting the incident light into electrical signals. Digital camera 200 further includes processor 208, memory 210, display 212, and one or more additional input/output (I/O) elements 214. Although shown as separate elements in the embodiment of FIG. 2, imaging stage 204 may be integrated with image sensor 206, and possibly one or more additional elements of digital camera 200, to form a compact camera module.

Processor 208 may be implemented, for example, as a microprocessor, a central processing unit (CPU), an application-specific integrated circuit (ASIC), a digital signal processor (DSP), or other processing device, or combinations of multiple such devices. Various elements of imaging stage 204 and image sensor 206 may be controlled by timing signals or other signals supplied from processor 208.

Memory 210 may be configured as any type of memory, such as, for example, random access memory (RAM), read-only memory (ROM), Flash memory, disk-based memory, removable memory, or other types of storage elements, in any combination. A given image captured by image sensor 206 may be stored by processor 208 in memory 210 and presented on display 212. Display 212 is typically an active matrix color liquid crystal display (LCD), although other types of displays may be used. The additional I/O elements 214 may include, for example, various on-screen controls, buttons or other user interfaces, network interfaces, or memory card interfaces.

It is to be appreciated that the digital camera shown in FIG. 2 may comprise additional or alternative elements of a type known to those skilled in the art. Elements not specifically shown or described herein may be selected from those known in the art. As noted previously, the present invention may be implemented in a wide variety of image capture devices.

Referring now to FIG. 3, there is shown a simplified block diagram of image sensor 206 shown in FIG. 2 in an embodiment in accordance with the invention. Image sensor 206 typically includes an array of pixels 300 that form an imaging area 302. Each pixel 300 includes four pixel edges 303 in the embodiment shown in FIG. 3. Combined pixel edges 303 form a perimeter or boundary around the components included in a pixel. As shown in FIG. 3, the four pixel edges 303 are arranged in the shape of a rectangle. Pixel edges 303 can be implemented in different shapes and orientations in other embodiments in accordance with the invention.

Image sensor 206 further includes column decoder 304, row decoder 306, digital logic 308, and analog or digital output circuits 310. Image sensor 206 is implemented as a back-illuminated Complementary Metal Oxide Semiconductor (CMOS) image sensor in an embodiment in accordance with the invention. Thus, column decoder 304, row decoder 306, digital logic 308, and analog or digital output circuits 310 are implemented as standard CMOS electronic circuits that are electrically connected to imaging area 302.

Functionality associated with the sampling and readout of imaging area 302 and the processing of corresponding image data may be implemented at least in part in the form of software that is stored in memory 210 and executed by processor 208 (see FIG. 2). Portions of the sampling and readout circuitry may be arranged external to image sensor 206, or formed integrally with imaging area 302, for example, on a common integrated circuit with photodetectors and other elements of the imaging area. Those skilled in the art will recognize that other peripheral circuitry configurations or architectures can be implemented in other embodiments in accordance with the invention.

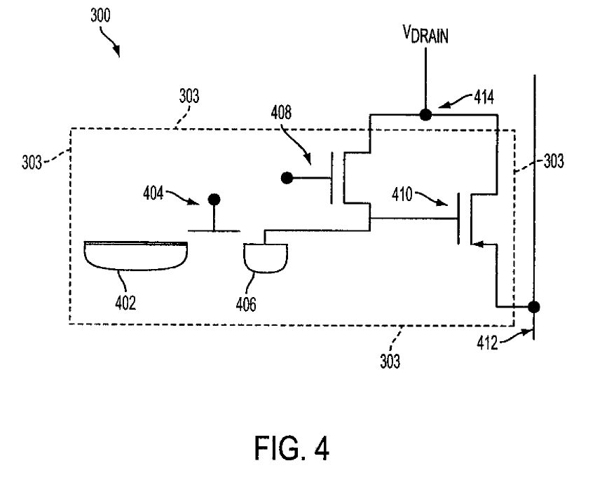

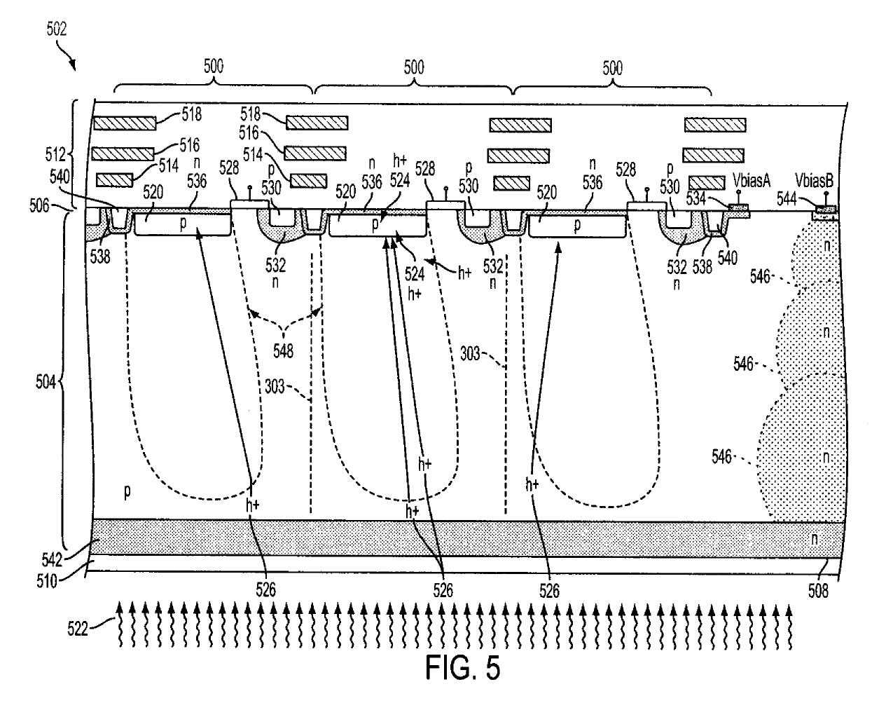

FIG. 4 is a schematic diagram illustrating an exemplary implementation for pixel 300 shown in FIG. 3. Pixel 300 is a non-shared pixel that includes within pixel edges 303 a photodetector 402, transfer gate 404, charge-to-voltage conversion mechanism 406, reset transistor 408, and amplifier transistor 410, whose source is connected to output line 412. The drains of reset transistor 408 and amplifier transistor 410 are maintained at potential Vdrain 414. The source of reset transistor 408 and the gate of amplifier transistor 410 are connected to charge-to-voltage conversion mechanism 406.

Photodetector 402 is configured as a pinned photodiode, charge-to-voltage conversion mechanism 406 as a floating diffusion, and amplifier transistor 410 as a source follower transistor in an embodiment in accordance with the invention. Pixel 300 can be implemented with additional or different components in other embodiments in accordance with the invention. By way of example only, photodetector 402 is configured as an unpinned photodetector in another embodiment in accordance with the invention.

Transfer gate 404 is used to transfer collected photo-generated charges from the photodetector 402 to charge-to-voltage conversion mechanism 406. Charge-to-voltage conversion mechanism 406 is used to convert the photo-generated charge into a voltage signal. Amplifier transistor 410 buffers the voltage signal stored in charge-to-voltage conversion mechanism 406 and amplifies and transmits the voltage signal to output line 412. Reset transistor 408 is used to reset charge-to-voltage conversion mechanism 406 to a known potential prior to readout. Output line 412 is connected to readout and image processing circuitry (not shown). As shown, the embodiment in FIG. 4 does not include a row select transistor when the image is read out using pulsed power supply mode, which involves controlling potential Vdrain 414 during readout.

Embodiments in accordance with the invention are not limited to the pixel structure shown in FIG. 4. Other pixel configurations can be used in other embodiments in accordance with the invention. By way of example only, a four transistor (4T) and shared pixel structures can be implemented in embodiments in accordance with the invention.

Referring now to FIG. 5, there is shown a cross-sectional view of a portion of a first back-illuminated image sensor in an embodiment in accordance with the invention. The cross-sectional view depicts three exemplary pixels 500 of the image sensor 502. The image sensor 502 includes an active silicon sensor layer 504 with a frontside 506 and a backside 508 opposite the frontside 506. Insulating layer 510 is disposed over backside 508 and circuit layer 512 is adjacent to frontside 506, such that sensor layer 504 is situated between circuit layer 512 and insulating layer 510. In the illustrated embodiment, insulating layer 510 is fabricated of silicon dioxide or another suitable dielectric material. Circuit layer 512 includes conductive interconnects 514, 516, 518, such as gates and connectors that form control circuitry for image sensor 502.

Each pixel 500 includes a photodetector 520 for converting light 522 incident on backside 508 into photo-generated charges 524, 526. Photodetectors 520 are disposed adjacent to frontside 506. In the illustrated embodiment, sensor layer 504 is implemented as an epitaxial layer having a p conductivity type, and photodetectors 520 are formed by implanting one or more dopants having a p conductivity type into the epitaxial layer.

Transfer gate 528 is used to transfer collected photo-generated charges from a respective photodetector 520 to a p conductivity type charge-to-voltage conversion mechanism 530, which is configured as a floating diffusion in the illustrated embodiment. Charge-to-voltage conversion mechanism 530 resides in a shallow well 532 of an n conductivity type.

One or more regions having an n-type conductivity are formed in at least a portion of sensor layer 504 adjacent to frontside 506 and are electrically connected to a voltage terminal 534 for biasing the n-type regions to a predetermined voltage. In the illustrated embodiment, the n-type regions adjacent to frontside 506 include the shallow n-well 532 surrounding charge-to-voltage conversion mechanism 530, the shallow n-well surrounding the p+ nodes of reset and source/follower transistors (not shown), the n-type pinning layer 536 disposed over each photodetector 520, and the n-type pinning layer 538 that lines the shallow trench isolation (STI) 540. The n-type regions adjacent to frontside 506 are biased to a known voltage level VbiasA through voltage terminal 534. Although not shown in FIG. 5, each of the shallow n-wells 532 surrounding each charge-to-voltage conversion mechanism 530 are continuously electrically connected together by other n-type implant regions such as the n-type pinning layers 536, 538.

A backside well 542 having an n conductivity type, which is a deep n-well in some embodiments, is formed in sensor layer 504 adjacent to backside 508, and is electrically connected to voltage terminal 544 through n-type connecting regions 546. In most embodiments, voltage terminal 544 is positioned at the edge of the imaging array. Backside well 542 is biased to a known voltage level VbiasB through voltage terminal 544. In one or more embodiments in accordance with the invention, a ground bias between VbiasA 534 and VbiasB 544 is included to eliminate biasing problems during power-up.

For a PMOS image sensor, VbiasB is more positive than VbiasA. This creates an electric field between the backside well 542 and frontside regions 532, 536, 538. This electric field drives photo-induced holes 526 toward the surface of frontside 506, thereby reducing electrical crosstalk. One desirable result of biasing backside well 542 at a higher voltage potential than the frontside regions 532, 536, 538 is the increased size of the depletion region 548 of each photodetector 520.

A few differences between the prior art NMOS configuration in United States Patent Application 2008/0217723 A1 and the embodiment illustrated in FIG. 5 will now be described. First, for the NMOS configuration, the backside electrode forms an ohmic connection to the p-epitaxial sensor layer, while in the embodiment of FIG. 5, the backside well 542 forms a reversed biased n-p junction between voltage terminal 544 and the p-epitaxial layer of the sensor layer 504. Second, for the prior art NMOS configuration, the transistor nodes adjacent to the frontside must reside in the triple well (p layer, n layer, p layer), increasing the footprint of the pixel transistors and reducing the size of the photodetector. In the embodiment of FIG. 5, a triple well is not needed due to the p-type epitaxial material used to form sensor layer 504. Third, for the prior art NMOS configuration, the STI also resides in a triple well, further reducing the size of the photodetector, while in the FIG. 5 embodiment the STI does not require any well implants. Fourth, for the prior art NMOS configuration, the p+ pinning implant must be pulled back from the transfer gate in order to isolate the p+ implant from the p− epitaxial layer, thereby degrading lag performance. In the embodiment of FIG. 5, however, the n+ region 536 is self-aligned to transfer gate 528. Fifth, in the prior art NMOS configuration, the region of the triple well just under the transfer gate can create a very high electric field region that enhances bright point generation due to contaminates and implant damage. The embodiment of FIG. 5 does not create this high electric field region because it uses the same transfer gate implant scheme as a standard frontside PMOS image sensor, eliminating the need for a sharp junction. Finally, since the transistors in the FIG. 5 embodiment do not require a triple well, the transistors takes up less area allowing the photodetectors to be larger, thereby resulting in better pixel performance.

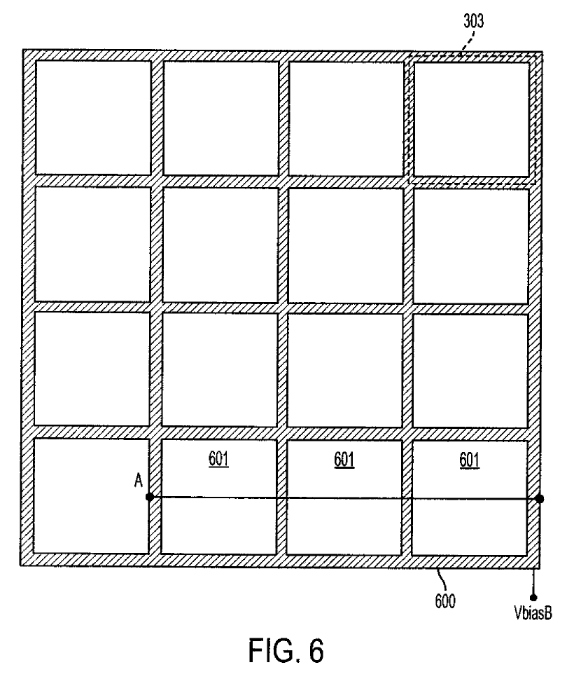

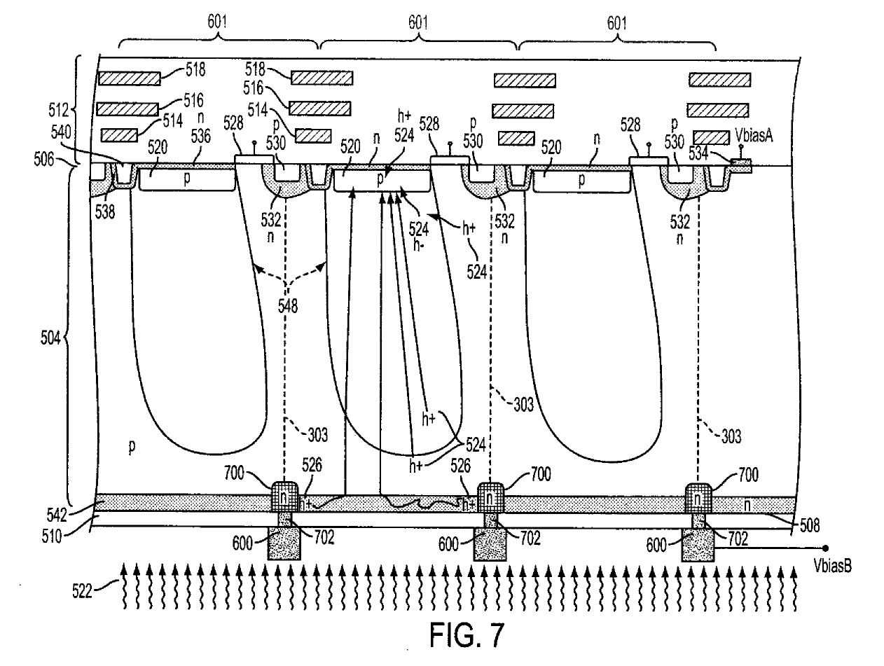

FIG. 6 is a top view of a portion of a second back-illuminated image sensor and an electrically bias light shield in an embodiment in accordance with the invention. An electrically conducting material, such as, for example, opaque lightshield 600 overlies and shadows pixel edges 303 (depicted with dashed lines) between neighboring pixels 601 in an embodiment in accordance with the invention (some pixel edges also shown in FIGS. 5, 7, 8). This shadowing improves crosstalk performance by reducing the number of photo-generated carriers created in the near vicinity of pixel edges 303. Opaque lightshield 600 is electrically connected to the voltage potential VbiasB in this embodiment.

Although the embodiment shown in FIG. 6 depicts the electrically conducting material as a lightshield, other embodiments in accordance with the invention can implement the electrically conductive material differently. By way of example only, the electrically conducting material can be fabricated as a transparent electrically conducting material. Additionally, the electrically conducting material is not limited to the shape shown in FIG. 6 (a rectangular shape that includes an array of rectangles). The shape of the electrically conducting material, or at least a portion of the electrically conducting material, can be shaped or orientated differently in other embodiments in accordance with the invention. For example, the electrically conducting material can have a shape that corresponds to one or more pixel edges 303, such as a single or multiple vertical or horizontal lines, one or more “L” shapes, or a large rectangle that surrounds the pixels on the edges of the imaging area, in one or more embodiments in accordance with the invention.

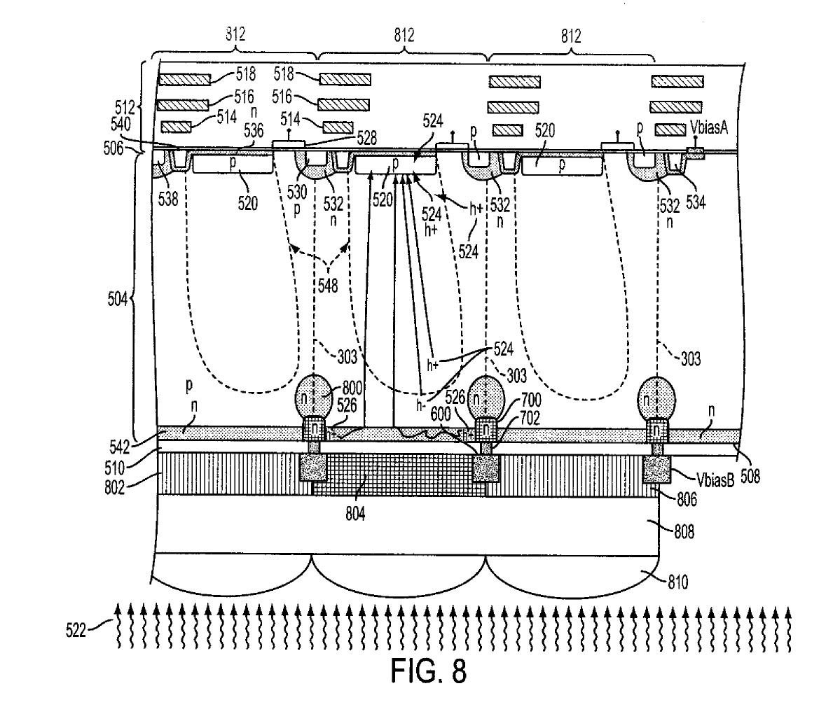

Referring now to FIG. 7, there is shown a cross-sectional view through the line A-A′ shown in FIG. 6. The embodiment shown in FIG. 7 is similar to the embodiment shown in FIG. 6 except for opaque lightshield 600, one or more contact implant regions 700, and one or more contacts 702 that electrically connect the contact implant regions 700 to lightshield 600. Contact implant region 700 is implanted with one or more dopants having an n conductivity type in the embodiment shown in FIG. 7. Typically, the concentration of the dopants in contact implant region 700 is greater than the dopant concentration in n-type backside well 542 to provide better electrical contact to backside well 542.

Opaque lightshield 600 and contacts 702 are formed from the same material, such as a single metal, in an embodiment in accordance with the invention. Other embodiments in accordance with the invention can fabricate lightshield 600 and contacts 702 from different materials, such as aluminum and tungsten.

The second voltage terminal 544 and connecting regions 542 are not included in the embodiment of FIG. 7. Instead, backside well 542 is biased to the known voltage level VbiasB through the electrically-biased lightshield 600, electrically conductive contacts 702, and contact implant regions 700. In another embodiment in accordance with the invention, voltage terminal 544 is disposed on frontside 506 and electrically connected to lightshield 600 using connecting regions 546, well 542, contact implant regions 700, and contacts 702.

As discussed earlier, VbiasB is greater than VbiasA in a PMOS image sensor. This potential difference creates an electric field between the n-type backside well 542 and n-type contact implant regions 700 and the frontside n-type regions 532, 536, 538. This electric field drives most photoinduced holes 524, 526 toward the surface of frontside 508, reducing electrical crosstalk as well as increasing the size of depletion region 548. Additionally, contact implant regions 700 steer the photoinduced holes 526 in backside well 542 towards the center of each pixel. The fringing electric fields from lightshield 600 also help steer photoinduced holes 526 toward the center of each pixel. This steering improves device MTF and reduces color crosstalk, especially for blue light.

FIG. 8 is a cross-sectional view of a portion of a third back-illuminated image sensor in an embodiment in accordance with the invention. The embodiment shown in FIG. 8 is similar to the embodiment shown in FIG. 7, but with the additions of chained contact implant regions 700, 800. The two or more contact implant regions 700, 800 can better steer the photo-induced holes within pixel edges 303. FIG. 8 also adds color filter elements 802, 804, 806 of a color filter array (CFA), spacer layer 808, and microlenses 810. Microlenses 810 focus light 522 towards the center of pixels 812. This yields an image sensor with good MTF and very low color crosstalk.

The invention has been described in detail with particular reference to certain preferred embodiments thereof, but it will be understood that variations and modifications can be effected within the spirit and scope of the invention. For example, the present invention has been described with reference to a PMOS back-illuminated image sensor. Other embodiments in accordance with the invention can reverse the conductivity types in a back-illuminated image sensor.

Additionally, even though specific embodiments of the invention have been described herein, it should be noted that the application is not limited to these embodiments. In particular, any features described with respect to one embodiment may also be used in other embodiments, where compatible. And the features of the different embodiments may be exchanged, where compatible.

### PARTS LIST

102 frontside of sensor layer
104 sensor layer
106 circuit layer
108 backside of sensor layer
110 insulating layer
112 light
114 photodetector
116 metallization level
118 transfer gate
120 frontside contact
122 well
124 backside contact
126 region
128 pixel
130 electrons
132 implant
134 charge-to-voltage conversion mechanism
136 implant
138 implant
200 image capture device
202 light
204 imaging stage
206 image sensor
208 processor
210 memory
212 display
214 other I/O
300 pixel
302 imaging area
303 pixel edge
304 column decoder
306 row decoder
308 digital logic
310 analog or digital output circuits
402 photodetector
404 transfer gate
406 charge-to-voltage conversion mechanism
408 reset transistor
410 amplifier transistor
412 output line
414 potential
500 pixel
502 image sensor
504 sensor layer
506 frontside of sensor layer
508 backside of sensor layer
510 insulating layer
512 circuit layer
514 interconnect
516 interconnect
518 interconnect
520 photodetector
522 light
524 charge
526 charge
528 transfer gate
530 charge-to-voltage conversion mechanism
532 region
534 voltage terminal
536 region
538 region
540 shallow trench isolation
542 backside well
544 voltage terminal
546 connecting region
548 depletion region
600 electrically conducting material configured as a lightshield
601 pixel
700 contact implant region
702 contact
800 contact implant region
802 color filter element
804 color filter element
806 color filter element
808 spacer layer
810 microlens
812 pixel

1. A back-illuminated image sensor, comprising:
a sensor layer of a first conductivity type having a frontside and a backside opposite the frontside, wherein the sensor layer is disposed between a circuit layer adjacent to the frontside and an insulating layer disposed over the backside;
one or more regions of a second conductivity type formed in at least a portion of the sensor layer adjacent to the frontside and electrically connected to a first voltage terminal for biasing the one or more regions at a first predetermined voltage; and
a backside well of the second conductivity type formed in the sensor layer adjacent to the backside and electrically connected to a second voltage terminal for biasing the backside well at a second predetermined voltage that is different from the first predetermined voltage.

2. The back-illuminated image sensor as in claim 1, wherein the well of the second conductivity type is electrically connected to the second voltage terminal through one or more connecting regions of the second conductivity type.

3. The back-illuminated image sensor as in claim 1, wherein the backside well of the second conductivity type is connected directly to the second voltage terminal.

4. The back-illuminated image sensor as in claim 1, further comprising:
a plurality of photodetectors of the first conductivity type for converting light incident on the backside into photo-generated charges, each photodetector having a depletion region, wherein the plurality of photodetectors are disposed in the sensor layer adjacent the frontside;
a plurality of charge-to-voltage conversion mechanisms of the first conductivity type disposed in the sensor layer adjacent to the frontside; and
a transfer gate for electrically connecting each charge-to-voltage conversion mechanism to a respective photodetector.

5. The back-illuminated image sensor as in claim 1, wherein the first conductivity type comprises a p conductivity type and the second conductivity type comprises an n conductivity type.

6. A back-illuminated image sensor, comprising:
a sensor layer of a first conductivity type having a frontside and a backside opposite the frontside, wherein the sensor layer is disposed between a circuit layer adjacent to the frontside and an insulating layer disposed over the backside;
one or more regions of a second conductivity type formed in at least a portion of the sensor layer adjacent to the frontside and electrically connected to a first voltage terminal for biasing the one or more regions at a first predetermined voltage;
a backside well of the second conductivity type formed in the sensor layer adjacent to the backside;
a second voltage terminal disposed on the frontside of the sensor layer; and
one or more connecting regions of the second conductivity type disposed between and electrically connected to the backside well and the second voltage terminal for biasing the backside well at a second predetermined voltage that is different from the first predetermined voltage.

7. The back-illuminated image sensor as in claim 6, further comprising:
a plurality of photodetectors of the first conductivity type for converting light incident on the backside into photo-generated charges, each photodetector having a depletion region, wherein the plurality of photodetectors are disposed in the sensor layer adjacent the frontside;
a plurality of charge-to-voltage conversion mechanisms of the first conductivity type disposed in the sensor layer adjacent to the frontside; and
a transfer gate for electrically connecting each charge-to-voltage conversion mechanism to a respective photodetector.

8. The back-illuminated image sensor as in claim 6, wherein the first conductivity type comprises a p conductivity type and the second conductivity type comprises an n conductivity type.

9. An image capture device, comprising:
a back-illuminated image sensor, comprising:
a sensor layer of a first conductivity type having a frontside and a backside opposite the frontside, wherein the sensor layer is disposed between a circuit layer adjacent to the frontside and an insulating layer disposed over the backside;
one or more regions of a second conductivity type formed in at least a portion of the sensor layer adjacent to the frontside and electrically connected to a first voltage terminal for biasing the one or more regions at a first predetermined voltage;
a backside well of the second conductivity type formed in the sensor layer adjacent to the backside;
a second voltage terminal disposed on the frontside of the sensor layer; and
one or more connecting regions of the second conductivity type disposed between and electrically connected to the backside well and the second voltage terminal for biasing the backside well at a second predetermined voltage that is different from the first predetermined voltage.
